(19) United States
(12) Patent Application Publication
(10) Pub. No.: US 2026/0099087 A1
(43) Pub. Date: Apr. 9, 2026

(54) METHODS OF MANUFACTURING SEMICONDUCTOR DEVICE AND EXTREME ULTRAVIOLET PHOTOLITHOGRAPHY SYSTEMS

(71) Applicant: Taiwan Semiconductor Manufacturing Company, Ltd., Hsinchu (TW)

(72) Inventors: Chih-Feng LU, Hsinchu (TW); Shang-Chieh CHIEN, Hsinchu (TW); Yen-Hsun CHEN, Hsinchu (TW); Han-Lung CHANG, Hsinchu (TW); Yi-Zhen CHEN, Hsinchu (TW); Li-Jui CHEN, Hsinchu (TW)

(73) Assignee: Taiwan Semiconductor Manufacturing Company, Ltd., Hsinchu (TW)

(21) Appl. No.: 18/908,373

(22) Filed: Oct. 7, 2024

(51) Int. Cl. G03F 1/24; G03F 7/00; G06T 7/00

(52) U.S. Cl. CPC G03F 1/24; G03F 7/70033; G03F 7/70925; G06T 7/001; G06T 2207/30148

(57) ABSTRACT

A method of manufacturing a semiconductor device includes conditioning a reflective surface of an extreme ultraviolet (EUV) mask, capturing an image of the conditioned reflective surface, performing a photolithography process using the mask, capturing another image of the reflective surface after the photolithography process, and comparing the images of the reflective surface. A system for EUV photolithography includes a conditioning unit, an inspection tool, an EUV exposure device, and a computing system programmed to control the conditioning unit, the inspection tool, and the EUV exposure device.

### BACKGROUND

Technological advances in semiconductor manufacturing have produced smaller and more complex circuits. With the evolution of semiconductor device technology, the number of devices per unit of area has increased as the size of the devices has decreased. Some semiconductor fabrication processes utilize extreme ultraviolet (EUV) photolithography, in which an EUV light is directed to a photomask that reflects a light pattern onto a photoresist disposed on a substrate. The photoresist is patterned by the light pattern and can be used to form structures in the underlying substrate. Imperfections or contamination on the reflective surface of a photomask can be transferred to the photoresist and the underlying substrate during manufacturing processes. Therefore, inspection and qualification of photomasks form a part of the photolithography process.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 shows an extreme ultraviolet lithography tool according to an embodiment of the disclosure.

FIG. 2 shows a schematic diagram of a detail of an extreme ultraviolet lithography tool according to an embodiment of the disclosure.

FIG. 3 shows a cross-sectional view of an EUV mask according to an embodiment of the present disclosure.

FIG. 4 shows a schematic representation of contamination of EUV mask with organic material.

FIG. 5 shows a schematic representation of removal of organic material from an EUV mask according to an embodiment of the present disclosure.

FIG. 6A shows a schematic representation of an image of a reflective surface of an EUV mask according to an embodiment of the present disclosure.

FIG. 6B shows a schematic representation of a portion of the image shown in FIG. 6A according to an embodiment of the present disclosure.

FIG. 7A shows a schematic representation of a grayscale golden image of a reflective surface of EUV mask according to an embodiment of the present disclosure.

FIG. 7B shows a schematic representation of a second grayscale image of the reflective surface shown in FIG. 7A after using the EUV mask in a photolithography process according to an embodiment of the present disclosure.

FIG. 7C. shows a map of defects or contamination produced by comparing the image in FIG. 7B with the image in FIG. 7A according to an embodiment of the present disclosure.

FIG. 8 shows a graph of an increase in grayscale reflectance of a reflective surface of an EUV mask during the use of the EUV mask in EUV processing.

FIGS. 9 and 10 show graphs illustrating differences in grayscale reflectance a EUV mask captured at different times during the use of the EUV mask in EUV processing.

FIG. 11 shows a graph of trendlines corresponding to sources of EUV scan failures and a region where a bright-dark effect persists.

FIG. 12 shows a schematic view of an inspection tool provided with a conditioning unit according to an embodiment of the disclosure.

FIG. 13 shows a schematic view of an EUV exposure device provided with a conditioning unit according to an embodiment of the disclosure.

FIG. 14 shows a schematic view of a mask library provided with a conditioning unit according to an embodiment of the disclosure.

FIG. 15 shows a schematic view of a stoker provided with a conditioning unit according to an embodiment of the disclosure.

FIG. 16 shows a schematic view of a hydrogen radical generator according to an embodiment of the disclosure.

FIG. 17 shows a schematic view of an ozone treatment unit according to an embodiment of the disclosure.

FIG. 18 shows a schematic view of a thermal treatment unit according to an embodiment of the disclosure.

FIG. 19 shows a schematic view of an inductively coupled plasma reactive ion etching unit according to an embodiment of the disclosure.

FIG. 20 shows a schematic view of EUV photolithography system according to an embodiment of the disclosure.

FIG. 21 shows a schematic view of a computing system according to an embodiment of the disclosure.

FIGS. 22, 23, and 24 are flow charts of methods of manufacturing a semiconductor device according to embodiments of the disclosure.

### DETAILED DESCRIPTION

It is to be understood that the following disclosure provides many different embodiments, or examples, for implementing different features of the disclosure. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper,” “top,” “bottom,” “middle,” and the like, may be used herein for ease of description to describe one element or feature's relationship to another element(s) or feature(s) as illustrated in the figures, and do not preclude additional structures above or below or between the stated features. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.”

Further, in the following fabrication process, there may be one or more additional operations in between the described operations, and the order of operations may be changed. In the present disclosure, a phrase “one of A, B and C” means “A, B and/or C (A, B, C, A and B, A and C, B and C, or A, B and C), and does not mean one element from A, one element from B and one element from C, unless otherwise described. In the following embodiments, materials, configurations, dimensions, processes and/or operations as described with respect to one embodiment (e.g., one or more figures) may be employed in the other embodiments, and detailed description thereof may be omitted.

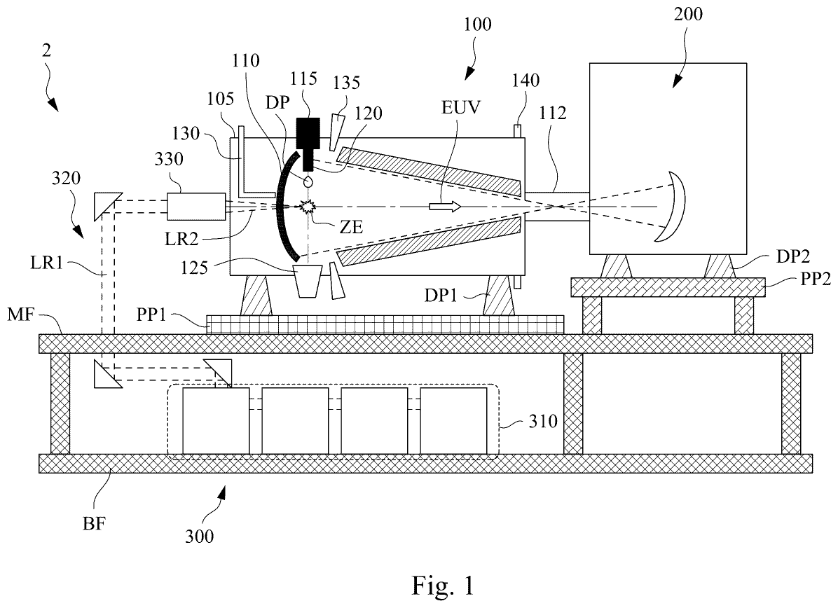

FIG. 1 is a schematic view of an EUV lithography tool 2, in accordance with some embodiments of the present disclosure. The tool 2 includes an EUV radiation source 100 to generate EUV radiation, an exposure device 200, such as a scanner, and an excitation laser source 300. The EUV radiation source 100 and the exposure device 200 are installed on a main floor MF of a clean room, while the excitation laser source 300 is installed in a base floor BF located under the main floor. The EUV radiation source 100 and the exposure device 200 are placed over pedestal plates PP1 and PP2 via dampers DP1 and DP2, respectively. The EUV radiation source 100 and the exposure device 200 are coupled to each other by a coupling mechanism 112, which may include a focusing unit. Gas in the radiation source 100 can travel through the coupling mechanism 112 into the exposure device 200.

The EUV lithography tool is designed to expose a photoresist layer to EUV light (also referred to as EUV radiation). The photoresist layer is a material sensitive to the EUV light. The EUV lithography system employs the EUV radiation source 100 to generate EUV light, such as EUV light having a wavelength ranging between about 1 nm and about 100 nm. The wavelength is centered at about 13.5 nm, according to some embodiments. In the present embodiment, the EUV radiation source 100 utilizes a mechanism of laser-produced plasma to generate the EUV radiation.

The exposure device 200 includes various reflective optic components, such as convex/concave/flat mirrors, a mask holding mechanism including a mask stage, and wafer holding mechanism. The EUV radiation generated by the EUV radiation source 100 is guided by the reflective optical components onto a mask secured on the mask stage. In some embodiments, the mask stage includes an electrostatic chuck (e-chuck) to secure the mask.

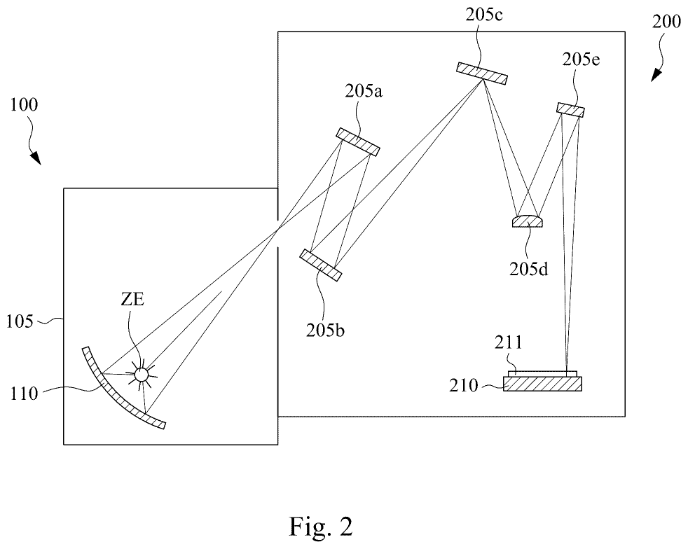

FIG. 2 is a simplified schematic diagram of a detail of an extreme ultraviolet lithography tool according to an embodiment of the disclosure. The EUV tool includes an EUV radiation source 100 including an EUV light radiator ZE emitting EUV light in a chamber 105 that is reflected by a collector mirror 110 along a path into the exposure device 200 to irradiate a photoresist 211 disposed on a substrate 210 with a patterned beam of EUV light. The exposure device 200 is provided with one or more optics 205a, 205b, for example, to illuminate an EUV mask 205c with a beam of EUV light, to produce a patterned beam, and one or more reduction projection optics 205d, 205e, for projecting the patterned beam onto the photoresist 211 disposed on the substrate 210. In various embodiments of the present disclosure, the substrate 210, which is coated with photoresist 211, is a semiconductor wafer, such as a silicon wafer or other type of wafer to be patterned. A mechanical assembly (not shown) may be provided for generating a controlled relative movement between the substrate 210 and the mask 205c. The EUV tool further includes other modules or is integrated with (or coupled with) other modules in some embodiments.

As shown in FIG. 1, the EUV radiation source 100 includes a target droplet generator 115 and a collector mirror 110, enclosed by a chamber 105. In various embodiments, the target droplet generator 115 includes a reservoir to hold a source material and a nozzle 120 through which target droplets DP of the source material are supplied into the chamber 105. In some embodiments, the target droplets DP are droplets of tin (Sn), lithium (Li), or an alloy of Sn and Li. In some embodiments, the target droplets DP each have a diameter in a range from about 10 microns (μm) to about 100 μm. An excitation laser LR2 generated by the excitation laser source 300 can be a pulse laser. The excitation laser source 300 may include a laser generator 310, laser guide optics 320, and a focusing apparatus 330. In some embodiments, the laser generator 310 includes a carbon dioxide (CO₂) or a neodymium-doped yttrium aluminum garnet (Nd: YAG) laser source with a wavelength in the infrared region of the electromagnetic spectrum. The laser light LR1 generated by the excitation laser source 300 is guided by the laser guide optics 320 and focused into the excitation laser LR2 by the focusing apparatus 330, and then introduced into the EUV radiation source 100. In some embodiments, the excitation laser LR2 includes a pre-heat laser and a main laser.

In some embodiments, the excitation laser LR2 is directed through windows (or lenses) into the zone of excitation ZE. The windows are made of a suitable material substantially transparent to the laser beams. The generation of the pulse lasers is synchronized with the ejection of the target droplets DP through the nozzle 120. As the target droplets move through the excitation zone, the pre-pulses heat the target droplets and transform them into low-density target plumes. A delay between the pre-heat pulse and the main pulse is controlled to allow the target plume to form and to expand to an optimal size and geometry. In various embodiments, the pre-heat pulse and the main pulse have the same pulse-duration and peak power. When the main pulse heats the target plume, a high-temperature plasma is generated. The plasma emits EUV radiation EUV, which is collected by the collector mirror 110. The collector mirror 110 further reflects and focuses the EUV radiation for the lithography exposing processes performed through the exposure device 200. The droplet catcher 125 is used for catching excessive target droplets. For example, some target droplets may be purposely missed by the laser pulses.

In such an EUV radiation source 100, the plasma caused by the laser application creates physical debris, such as ions, gases and atoms of the droplet, as well as the desired EUV radiation. It is better to prevent the accumulation of material on the collector mirror 110 and also to prevent physical debris from exiting the chamber 105 and entering the exposure device 200. According to some embodiments, a buffer gas is supplied from a first buffer gas supply 130 through an aperture in the collector mirror 110 by which the laser pulse is delivered to the tin droplets. The buffer gas can also be provided through one or more second buffer gas supplies 135 toward the collector mirror 110 and/or around the edges of the collector mirror 110. Further, the chamber 105 includes one or more gas outlets 140 so that the buffer gas is exhausted outside the chamber 105.

In some embodiments, the buffer gas is H₂, He, Ar, N₂, or another inert gas. In certain embodiments, diatomic hydrogen (H₂) gas is used as the buffer gas because hydrogen radicals (H⁺) generated by ionization of the buffer gas with the EUV radiation can be used for cleaning purposes. Hydrogen gas has low absorption to the EUV radiation. Hydrogen gas reaching the surface of the collector mirror 110 reacts chemically with a metal of the droplet forming a hydride, e.g., metal hydride. When tin (Sn) is used as the droplet, stannane (SnH₄), which is a gaseous byproduct of the EUV generation process, is formed. The gaseous SnH₄ is then pumped out through the outlet 140.

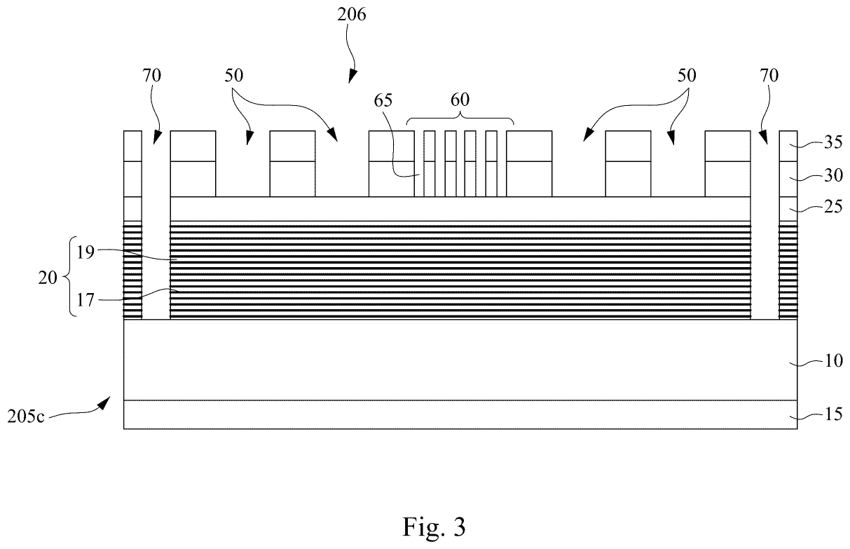

FIG. 3 shows a cross sectional view of an EUV mask 205c (or a reticle) according to an embodiment of the present disclosure. The EUV mask includes a multilayered stack 20 of molybdenum layers 17 and silicon layers 19 (“Mo/Si stack 20”). The Mo/Si stack 20 includes alternating Mo layers 17 and Si layers 19 disposed over a first major surface of a mask substrate 10. In some embodiments, the multilayered stack 20 includes alternating molybdenum layers 17 and beryllium layers 19. In some embodiments, the number of layers in the multilayered stack 20 is in a range from 20 to 100 although any number of layers is allowed as long as sufficient reflectance is maintained for imaging the target substrate.

A capping layer 25 is disposed over the stack 20. The capping layer 25 prevents oxidation of the multilayered stack 20 in some embodiments. In some embodiments, the capping layer 25 is formed of a material including ruthenium (Ru). In some embodiments, the capping layer is formed of Ru.

An EUV absorbing layer or absorber 30 is disposed over the capping layer 25. The absorber 30 absorbs radiation with wavelength in a range of EUV wavelengths. The absorber 30 can be formed of a single layer or multiple layers. In some embodiments, the absorber 30 is formed of a material including a tantalum compound. In some embodiments, the absorber 30 is made of TaN or TaBN. In some embodiments, the material used to make the absorber 30 also includes molybdenum, palladium, zirconium, nickel silicide, titanium, titanium nitride, chromium, chromium oxide, aluminum oxide, aluminum-copper alloy, or other suitable materials.

An anti-reflection layer 35 is disposed over the absorber 30 and is formed of formed of a material including SiO₂, SiN, TaBO, TaOs, Cr₂O₃, indium tin oxide (ITO), or any suitable material, in some embodiments of the present disclosure. The anti-reflection layer 35 reduces reflections of photolithographic radiation.

In some embodiments, a conductive backside coating layer 15 is optionally deposited on the second major surface of the mask substrate 10 opposite to the first major surface. The conductive backside coating layer 15 is used to fix the mask for photolithographic operation by electrostatic chucking in some embodiments. In an embodiment, the conductive layer 15 is formed of a ceramic compound including chromium nitride or any suitable material for electrostatic chucking of the mask.

The mask substrate 10 can be made of a low thermal expansion glass material including titanium oxide doped silicon dioxide, or any other suitable low thermal expansion materials such as quartz, silicon, silicon carbide, Black Diamond, and/or other low thermal expansion substances known in the art that can minimize the image distortion due to mask heating in the EUV photolithographic environment, in some embodiments of the present disclosure. The mask substrate 10 can have a low defect level, such as a high purity single crystal substrate, and a low level of surface roughness, as measured using an atomic force microscope.

FIG. 3 shows circuit patterns 50 formed on the EUV mask. The circuit patterns can be formed by removing sections of the anti-reflection layer 35 and the absorber 30. In addition, a black border area 70 surrounding a circuit pattern region and penetrating to the substrate is formed. Additional regions 60 include patterns 65 exposing the capping layer 25 are shown in FIG. 3.

In some embodiments of the present disclosure, circuit patterns 50 and black border areas 70 are formed in a EUV mask using a photolithography process. A hard mask layer can be disposed over the anti-reflection layer 35 and a photoresist layer can be disposed over the hard mask layer. The photoresist layer can be patterned using photolithographic techniques to form a photoresist pattern. The photoresist pattern can be extended into hard mask layer to form a hard mask layer pattern using suitable etching techniques, and the hard mask layer pattern can be extended through the anti-reflection layer 35 and the absorbing layer 30 using suitable etching techniques to expose the capping layer 25 and form the circuit patterns 50. The black border areas 70 can be similarly formed. According to some embodiments, a surface of an EUV mask 205c having circuit patterns 50 formed thereon is considered to be a reflective surface 206.

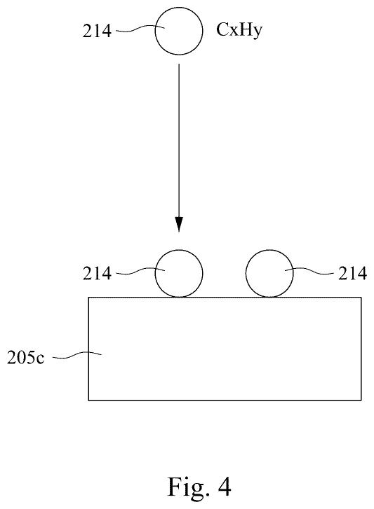

However, photolithography processes used to form an EUV mask can introduce organic material contamination, e.g., hydrocarbon material, to the mask. It is thought that residues or byproducts of the polymeric photoresist materials used during photolithographic manufacturing of EUV masks may not be fully removed upon cleaning a new mask. FIG. 4 schematically illustrates a mask 205c contaminated with organic material 214. Organic material contamination on a EUV mask be in the form of spotting, a monolayer, a bilayer, or any number of layers. The contamination can result from EUV mask production or may be fall-on contamination caused by use of the mask in EUV processes and handling. An EUV mask having a reflective surface contaminated with organic material can introduce errors in a photolithography process and adversely affect the critical dimension (CD) uniformity of a pattern formed in a photoresist layer.

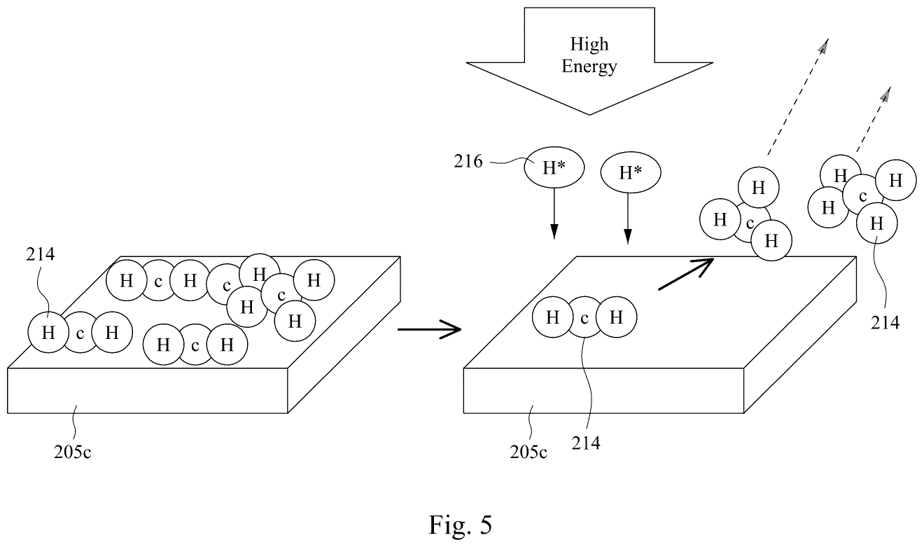

While EUV masks can be cleaned using solvents, such a process may introduce other undesired contaminants such as particles. As noted above, a H₂ buffer gas that is introduced into an EUV radiation source 100 can be converted into hydrogen radicals (H*) by EUV radiation generated in the EUV radiation device 100. The hydrogen radicals can serve to clean not only the collector mirror 110 but can also travel through the coupling mechanism 112 to the interior of the exposure device 200. Also, H₂ buffer gas present in an exposure device 200 can be converted into hydrogen radicals by the EUV radiation in the exposure device. The hydrogen radicals can clean surfaces of the mask 205c present in the exposure device. FIG. 5 schematically illustrates a process by which organic material 214 is removed from a reflective surface of an EUV mask 205c by reaction with hydrogen radicals 216 present in an exposure device. The mask 205c on the left side of the figure has organic material contamination at the time of new tape out of the mask. The mask 205c on the right side of the figure is being cleaned by high energy hydrogen radicals present in an exposure device. However, the cleaning process in an exposure device can be slow and cause a gradual undesired increase in reflectance of the EUV mask during a course of use in EUV processes. The increase in reflectance can cause errors when later inspecting the EUV mask for contamination or defects.

In some embodiments, one or more inspection tools are used to inspect EUV masks for defects and contamination before and after the use of the masks in a photolithography process. In some embodiments, an optical inspection tool includes a time delay integration (TDI) charge-coupled device (CCD) image sensor configured to capture images of a reflective surface of an EUV mask. In some embodiments, an image sensor of an inspection tool is configured to capture a grayscale image of a reflective surface of an EUV mask. In some embodiments, a grayscale image includes a plurality of regions, and each of the regions has a grayscale value.

In some embodiments, a reflective surface 206 of an EUV mask 205c as shown in FIG. 3 is scanned by an inspection tool to produce an image of the reflective surface. In some embodiments, the EUV mask 205c can be scanned after removing a pellicle from the mask. In some embodiments, the inspection tool directs light toward the reflective surface and captures an image of the light that is reflected back to an image sensor of the inspection tool. Features, e.g., pattern elements, defects, and contamination, present on a reflective surface of an EUV mask can reflect light having different intensities. The inspection tool or a computing system can process the images captured by the sensor into grayscale images by assigning grayscale values to different regions of the reflective surface of the EUV mask based on levels of light reflected from the different regions.

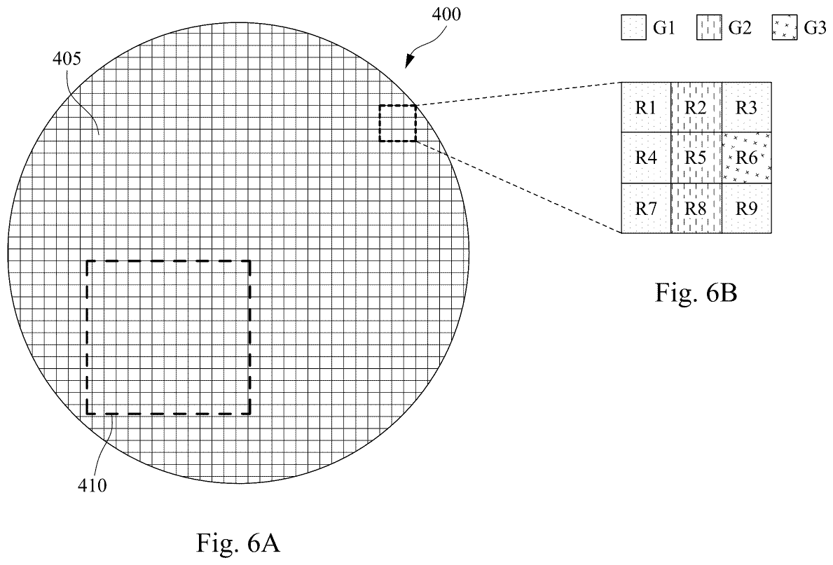

FIG. 6A schematically illustrates an image 400 of a reflective surface of an EUV mask captured by a sensor of an inspection tool, according to some embodiments. The image 400 is divided into a plurality of regions 405. In some embodiments, each of the regions 405 substantially corresponds to a pixel of the sensor of the inspection tool. In some embodiments, each region 405 is assigned a grayscale value, however FIG. 6A omits grayscale values to simplify illustration. FIG. 6B illustrates an enlarged portion of the image 400 shown in FIG. 6A and shows nine of the regions 405 having grayscale values, according to an embodiment. In the illustrated embodiment, the nine regions 405 of FIG. 6A that are shown in FIG. 6B are labeled R1, R2, R3, R4, R5, R6, R7, R8, and R9, and are assigned a grayscale value G1, G2, or G3, according to a reference grayscale standard. According to some embodiments, each region 405 of the image shown in FIG. 6A is assigned a grayscale value that corresponds to a defined range of grayscale intensity. In the embodiment illustrated in FIG. 6B, the G1 grayscale value corresponds to a range of grayscale intensity of 0-50, the, G2 grayscale value corresponds to a range of grayscale intensity of 51-100, and the G3 grayscale value corresponds to a range of grayscale intensity of 101-150.

To detect contaminants or defects present on a reflective surface of an EUV mask, two or more images of the reflective surface can be captured at separate stages of use of the EUV mask. In an embodiment, an inspection tool is used to capture a first grayscale image of a reflective surface of an EUV mask at time T₀. In an embodiment, time T₀ is the time of new tape out of mask, which is when a new mask is obtained from mask production and is ready for qualification for use in EUV processes. In another embodiment, time T₀ is a time of requalification of an EUV mask. In some embodiments, time T₀ is a time of cleaning an EUV mask or a time of verification that the reflective surface is free of defects and contamination and is designated as a golden image or standard image of the reflective surface. The golden image can include the regions 405 shown in FIG. 6A, where each region has a defined grayscale value.

A second grayscale image of a reflective mask can be captured at time T₁ (which can also be referred to as T_{now}). T₁ can generally be any time after time T₁. In various embodiments, time T₁ can correspond to a time after the EUV mask has been stored in a stoker, a time after the EUV mask has been stored in a mask library, a time after the EUV mask has been used to perform one or more EUV photolithography processes, or a time after the EUV mask is handled by robots or operators. After any use of an EUV mask, an optical inspection tool can be used to capture a second grayscale image of the reflective surface of the EUV mask at time T₁.

In some embodiments, a computing system compares a second grayscale image of a reflective surface of an EUV mask with a golden grayscale image of the reflective surface to determine if contaminants or defects are present on the reflective surface. In some embodiments, the comparison includes comparing grayscale values of a plurality of regions of the second grayscale image with grayscale values of corresponding regions of the golden image. In some embodiments, a computing system compares each region of the second grayscale image with a positionally corresponding region of the golden image. For example, region R1 shown in FIG. 6B of a second grayscale image is compared with region R1 of a golden image, region R2 of the second grayscale image is compared with region R2 of the golden image, and so forth until all the positionally corresponding regions are compared. In some embodiments, upon determining that a grayscale value of a region of the second grayscale image differs from a grayscale value of a positionally corresponding region of the golden image, the computing system records the region of the second grayscale image as having an artifact, e.g., a defect or contamination. In some embodiments, a computing system is configured to map a region of the reflective surface shown in the second grayscale image that has a different grayscale value than a positionally corresponding region of a golden grayscale image of the reflective surface.

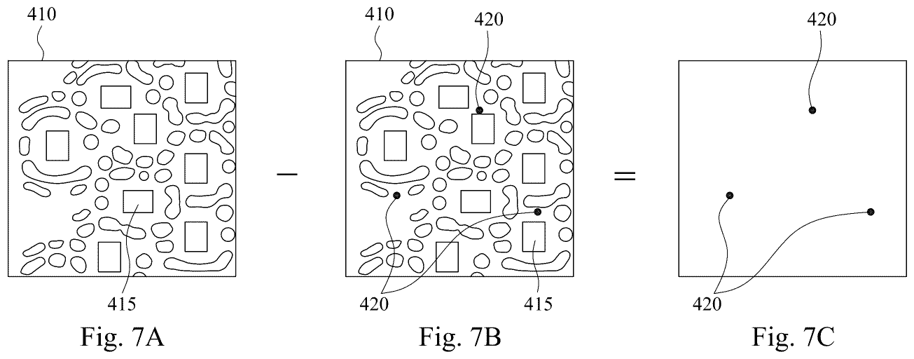

FIG. 7A illustrates an embodiment of a grayscale golden image of a reflective surface of EUV mask. FIG. 7B illustrates an embodiment of a second grayscale image of the reflective surface shown in FIG. 7A obtained after use of the EUV mask in a photolithography process. FIG. 7C. illustrates a map of defects or contamination produced by comparing the second grayscale image in FIG. 7B with the grayscale golden image in FIG. 7A, according to an embodiment. The pattern 415 shown in FIGS. 7A and 7B corresponds to area 410 of FIG. 6A. In FIG. 7B, three artifacts 420 are present in area 410. The artifacts are not present in area 410 of FIG. 7A. In some embodiments, a computing system compares the second grayscale image of FIG. 7B with the golden image in FIG. 7A and generates a map in FIG. 7C of three artifacts 420 by subtracting the second grayscale image of FIG. 7B from the grayscale golden image of FIG. 7A. The three artifacts 420 mapped in FIG. 7C correspond to locations where the grayscale values of regions in FIG. 7B differed from grayscale values of positionally corresponding regions shown in FIG. 7A. In some embodiments, the mapped locations of the artifacts 420 in FIG. 7C are used to further evaluate the reflective surface of the mask shown in FIG. 7B to determine whether the artifacts 420 are defects in the reflective surface or contamination.

However, the comparison of second grayscale image with a grayscale golden image of the same reflective surface can be susceptible to an undesired bright-dark effect. A bright-dark effect, as described below, can cause a grayscale image comparison to falsely detect defects or contaminants on a reflective surface. Organic material, e.g., hydrocarbons, may be present on a mask's reflective surface after the mask's production, or after handling or use of the mask in EUV processes. It is thought that organic material alters the reflectance of the reflective surface. It is also thought that organic material can induce the oxidation of ruthenium that is present on a reflective surface of an EUV mask, in some embodiments. A formula for oxidation and reduction of ruthenium is as follows:

$$Ru + \frac{x}{2} 02 ⇋ Ru0x , x = 2 , 3 , 4$$

Ruthenium oxide reduces the reflectance of the reflective surface.

If a golden image is captured while a reflective surface of a mask has organic material contamination or ruthenium oxidation, and the mask is subsequently used in EUV processing, the hydrogen radicals present in an EUV exposure device can gradually clean the reflective surface by removing the organic material and reducing ruthenium oxide to ruthenium. These gradual alterations in the reflective surface during EUV processing can increase the reflectance of the reflective surface of the mask over time. The gradual increase in reflectance can generate the bright-dark effect when a second grayscale image of the reflective surface, i.e., having the increased reflectance, is compared with an earlier obtained grayscale golden image of the same mask having lower reflectance. The increase in reflectance can cause an inspection tool or computing system to mistakenly flag differences in reflectance as the presence of defects or contamination.

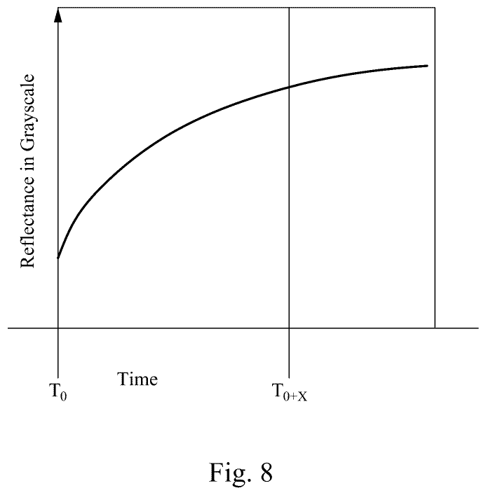

FIG. 8 illustrates a graph of the increase in grayscale reflectance of a reflective surface of an EUV mask from an initial measurement time T₀ through subsequent measurement times during the use of the mask in EUV processes. At time T₀, the reflective surface has one or more of organic material contamination or ruthenium oxidation. From times T₀ and T_{0+X}, the detected grayscale reflectance increases due to the cleaning and reducing effects of hydrogen radicals in the EUV tool. After times T_{0+X}, the increase in grayscale reflectance is more stable and gradual because the rate of cleaning and reduction of ruthenium oxide decreases. Due to the increase in reflectance and the bright-dark effect, a grayscale golden image of a reflective surface captured between T₀ and T_{0+X} may be unreliable for comparison with a later captured second grayscale image of the same reflective surface.

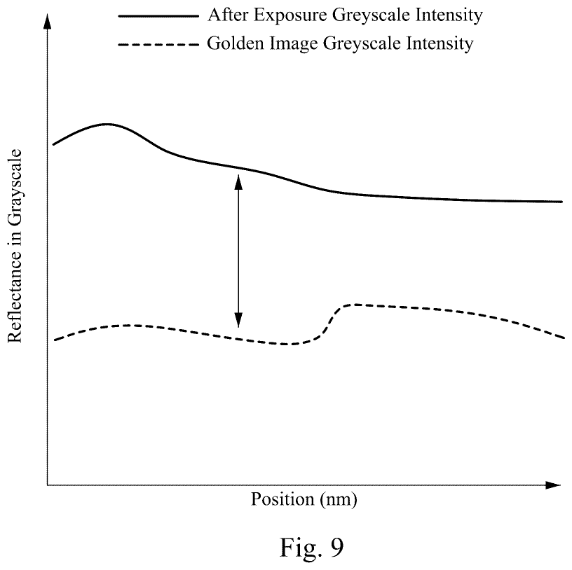

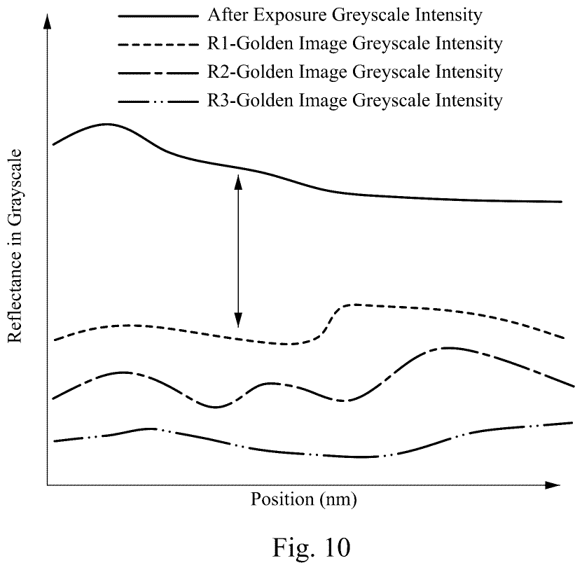

FIGS. 9 and 10 illustrate trendlines of differences in reflectance of golden grayscale images and second grayscale images based on position on a reflective surface of an EUV mask. In FIG. 9, the lower trendline corresponds to a grayscale golden image of a reflective surface having one or more of organic material contamination or ruthenium oxidation. The upper trendline represents a second grayscale image of the same reflective surface captured after using the mask in EUV processing that subjects the reflective surface to gradual cleaning with hydrogen radicals. In FIG. 10, the lower three trendlines correspond to grayscale golden images taken at three different focal points (R1, R2, R3) over a reflective surface of a mask having one or more of organic material contamination or ruthenium oxidation. The uppermost trendline in FIG. 10 corresponds to a second grayscale image of the same reflective surface captured after using of the mask in EUV processing that subjects the reflective surface to gradual cleaning with hydrogen radicals. A computing system or inspection tool comparing the grayscale golden images shown in FIGS. 9 and 10 with the second grayscale images could incorrectly flag regions of reflectance in the second grayscale images as having defects or contamination. While a computing system may conduct operations or run software to level or correct images, such operations or software may be insufficient to account for differences in grayscale reflectance caused by gradual cleaning or reduction of a reflective surface in an EUV tool. The increase in reflectance of a reflective surface may lead to the capture of a new golden image of the mask for use in later defect inspections of the mask. However, capturing new golden images can be undesirable due to increased demand on inspection tools and reduced production due to tools capturing new golden images instead of conducting routine defect inspections.

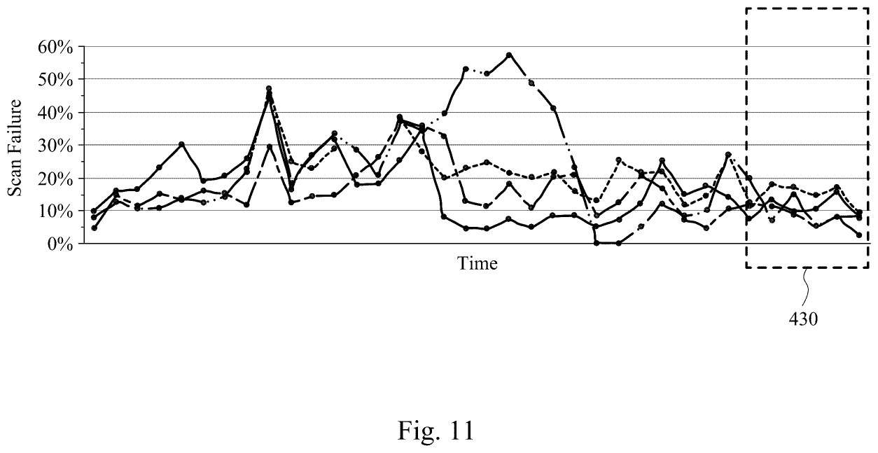

FIG. 11 illustrates four separate trendlines corresponding to four different sources of EUV scan failures. The annotated box 430 corresponds to a period of reduced EUV processing failures from the four sources. However, the bright-dark effect continues to occur within the period in the box 430 even after addressing the four sources of scan failure because the reflective surface of the EUV mask utilized in the EUV processes continues to be gradually cleaned or reduced by hydrogen radicals during exposure. If a bright-dark effect occurs for a reflective surface of an EUV mask, a new golden image of the reflective surface may be captured. The new golden image can be used for comparison with a later captured grayscale image of the same reflective surface. However, generating a new golden image requires the use of an inspection tool. A semiconductor fabrication facility may have a limited number of inspection tools and the tools may be under high demand.

Provided herein are methods, systems, and apparatuses for conditioning a reflective surface of a mask by removing organic material and/or reducing ruthenium oxidation before capturing a golden image. By removing organic material and/or reducing ruthenium oxide before capturing a golden image, it is thought that the reflective surface will be less susceptible to increased reflectance and the bright-dark effect due to the ordinary cleaning and reducing effects of EUV processes.

A reflective surface of a mask can be conditioned to remove organic material and/or reduce ruthenium oxide through a variety of different conditioning units. One or more conditioning units can be used at any point in a EUV photolithography process. In an embodiment, a conditioning unit includes a hydrogen radical generator configured to apply hydrogen radicals to a reflective surface of an EUV mask to achieve one or more of the removal of organic material and the reduction of ruthenium oxide on the reflective surface. In another embodiment, a conditioning unit is configured to supply ozone to a reflective surface of an EUV mask to achieve one or more of the removal of organic material and the reduction of ruthenium oxide on the reflective surface. In yet another embodiment, a conditioning unit includes a thermal treatment unit configured to thermally treat a reflective surface at a temperature high enough to achieve one or more of the removal of organic material and the reduction of ruthenium oxide on the reflective surface. In a further embodiment, a conditioning unit includes an inductively coupled plasma reactive ion etching unit configured to conduct an etching process to achieve one or more of the removal of organic material and the reduction of ruthenium oxide on the reflective surface.

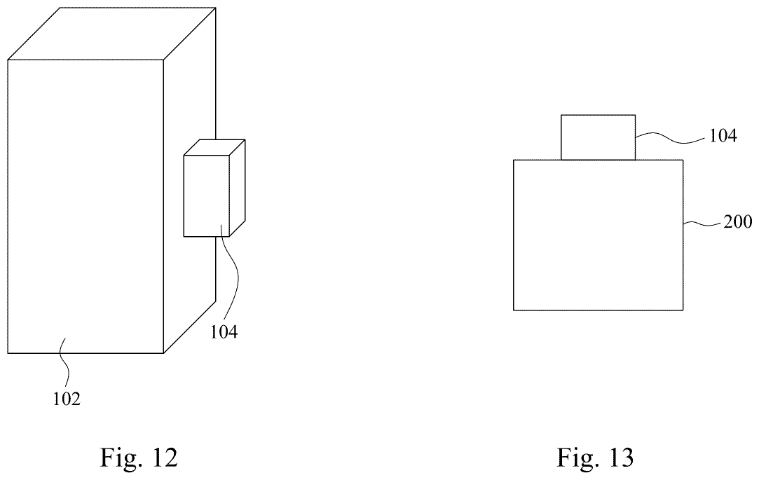

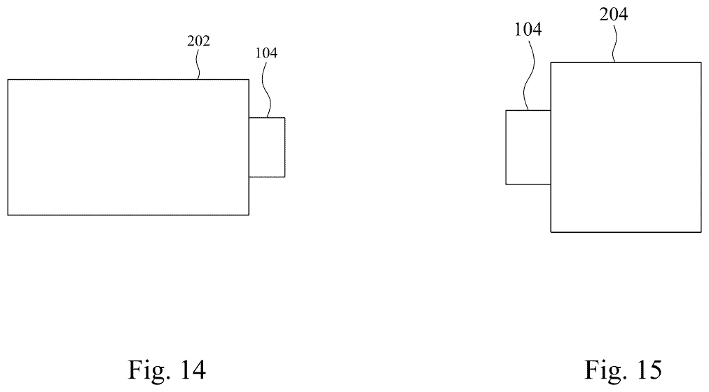

FIG. 12 schematically illustrates an embodiment of an inspection tool 102 provided with a conditioning unit 104. FIG. 13 schematically illustrates an embodiment of an EUV exposure device 200 having the features of an exposure device shown and described in connection with FIGS. 1 and 2 and provided with a conditioning unit 104. FIG. 14 schematically illustrates an embodiment of a mask library 202 provided with a conditioning unit 104. FIG. 15 schematically illustrates an embodiment of a stoker 204 provided with a conditioning unit 104. While FIGS. 12-15 schematically illustrate conditioning units 104 fixed to the exteriors of the housings of the illustrated apparatuses, the conditioning units 104 can also be provided inside the housings. A conditioning unit may also be provided as a standalone unit in an EUV photolithography system. A robot can be used to insert an EUV mask into a conditioning unit. Alternatively, an operator can manually insert an EUV mask into a conditioning unit. An EUV mask can be housed in a protective pod, with or without a pellicle, and a conditioning unit or other tool associated with the conditioning unit can have a robot or mechanism to remove the mask from the pod prior to conditioning.

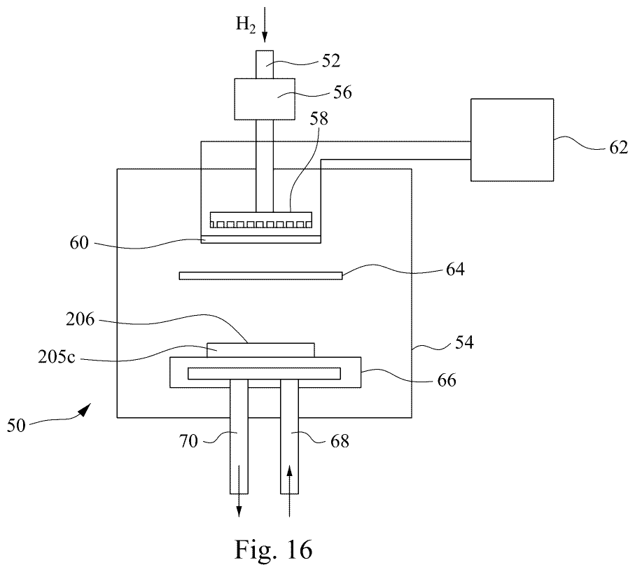

FIG. 16 schematically illustrates a hydrogen radical generator 50, according to an embodiment. A feed conduit 52 is configured to supply diatomic hydrogen (H₂) to a chamber 54. A mass flow controller 56 is configured to adjust the flow of diatomic hydrogen to the chamber. A shower head 58 connected to the end of the feed conduit is configured to supply diatomic hydrogen across a resistive heating wire 60, e.g., a tungsten wire, connected to a power supply 62. The heating wire is configured to supply sufficient energy to split the diatomic hydrogen into hydrogen radials (H*). The hydrogen radicals can fall across a shield 64 and contact a reflective surface 206 of a mask 205c that rests on a cooling stage 66. The cooling stage is provided with conduits 68,70 that are configured to circulate a coolant, e.g., water, to the cooling stage during the processing of the mask with the hydrogen radicals.

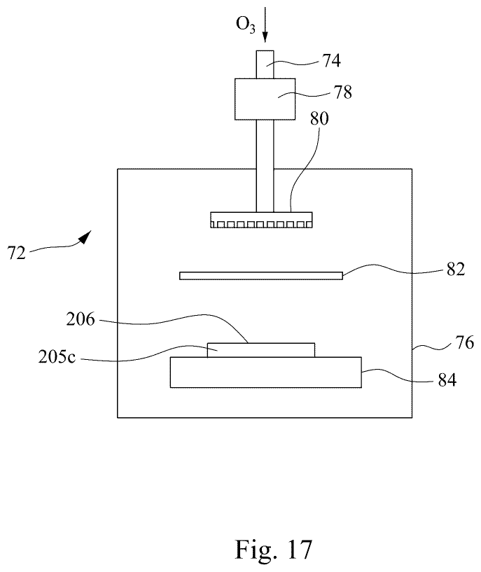

FIG. 17 schematically illustrates an ozone treatment unit 72 configured to supply ozone to a reflective surface of an EUV mask 72, according to an embodiment. A feed conduit 74 supplies ozone to a chamber 76. A mass flow controller 78 is configured to adjust the flow of ozone to the chamber. A shower head 80 connected to the end of the feed conduit is configured to supply ozone over a shield 82 before the ozone contacts a reflective surface 206 of a mask 205c that rests on a stage 84.

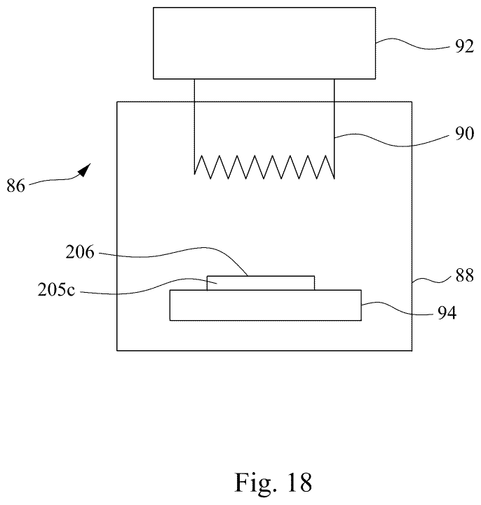

FIG. 18 schematically illustrates a thermal treatment unit 86, according to an embodiment. A chamber 88 is provided with a heating element 90 connected to a power supply 92. The heating element is disposed above a reflective surface 206 of a mask 205c that rests on a stage 94.

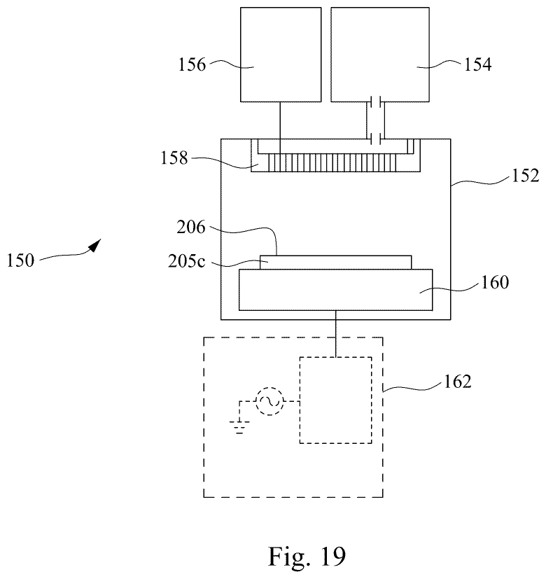

FIG. 19 schematically illustrates inductively coupled plasma reactive ion etching unit 150, according to an embodiment. A chamber 152 is provided with a generator including a plasma gas source 154, a first RF power supply 156, and an antenna 158. A stage 160 supports a mask 205c having a reflective surface 206 facing the antenna. The plasma gas source 154 is configured to supply an etchant gas such as O₂ and/or H₂. The first RF power supply 156 is connected to the antenna 158 and is configured to generate an RF signal to provide inductively coupled energy to etchant gas entering the chamber 152 from the plasma gas source 154. A plasma can be ignited when sufficient power is delivered to the etchant gas. A second RF power supply 162 is configured to selectively apply a bias voltage to the mask 205c.

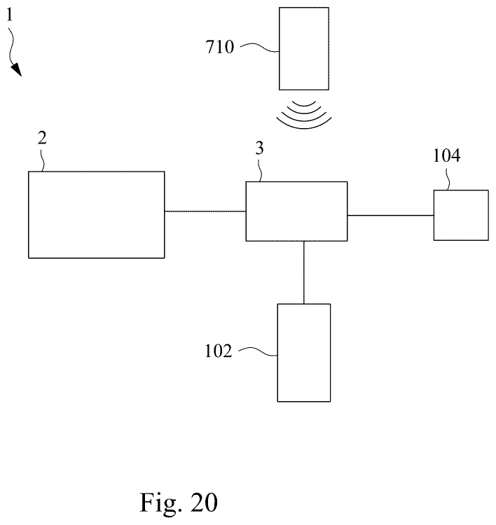

FIG. 20 schematically illustrates an embodiment of an EUV photolithography system 1 that includes an EUV lithography tool 2, a mask-handling system 3, an inspection tool 102, a conditioning unit 104, and a computing system 710. The EUV lithography tool 2 is configured to perform a photolithography process including directing EUV radiation to a reflective surface of an EUV mask to reflect a patterned beam of light from the reflective surface onto a photoresist layer disposed on a substrate. The inspection tool 102 is configured to capture a first image of the reflective surface of the EUV mask before the EUV exposure device performs the photolithography process. The inspection tool 102 is also configured to capture a second image of the reflective surface after the EUV exposure device performs the photolithography process. The conditioning unit 104 is configured to perform a conditioning process on the reflective surface of the EUV mask before the inspection tool 102 captures the first image. The conditioning can remove organic material from the reflective surface and/or reduce ruthenium oxide present on the reflective surface.

The computing system 710 can be programmed to operate components of the EUV photolithography system to perform any method provided in the present disclosure. In an embodiment, the computing system 710 is programmed to conduct operations including controlling the conditioning unit 104 to perform the conditioning of a reflective surface of an EUV mask before performing a photolithography process using the EUV mask, controlling the inspection tool 102 to capture a first image of the reflective surface after the conditioning of the reflective surface, controlling the EUV lithography tool 2 to perform the photolithography process after the inspection tool captures the first image, controlling the inspection tool 102 to capture a second image of the reflective surface after the photolithography process, and comparing the second image with the first image to determine the presence of at least one of a defect or contamination on the reflective surface. The computing system 710 can conduct the image comparison or control another system component, such as the inspection tool 102, to complete the comparison.

FIG. 20 illustrates the computing system 710 as being wirelessly connected to other components of the system 1. However, the computing system 710 can be hardwired to one or more of the components of the system 1. The computing system 5 is configured to compare the second image with the first image (e.g., golden image) to determine the presence of at least one of a defect or contamination on the reflective surface. In some embodiments, the computing system 710 controls a mask handling system 3 that transfers the EUV mask between any of the lithography tool 2, the inspection tool, and the conditioning unit. In other forms, an operator can manually transfer a mask between one or more of the tools and components of the system 1. The system can optionally include a stoker or mask library paired with or incorporating the conditioning unit 104. The conditioning unit 104 can also be paired with or incorporated into the inspection tool 102 or an exposure device of the EUV lithography tool 2.

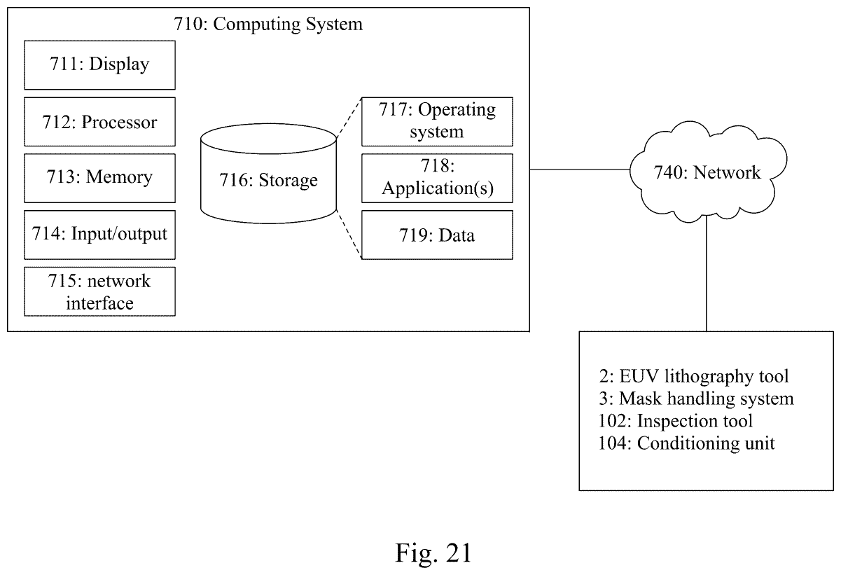

FIG. 21 is a block diagram illustrating an example of a computing system 710 for controlling the operation of the EUV lithography tool 2, the mask handling system 3, the inspection tool 102, and/or the conditioning unit 104, according to some embodiments. In some embodiments, the computing system 710 is implemented using hardware or a combination of software and hardware, either in a dedicated server, integrated into another entity, or distributed across multiple entities such as via a cloud or wired network. The computing system 710 is communicably connected to the EUV lithography tool 2, the mask handling system 3, the inspection tool 102, and/or the conditioning unit 104 using a wireless or wired network 740 to permit data exchange therebetween.

The computing system 710 includes a display 711, a processor 712, a memory 713, an input/output interface 714, a network interface 715, and a storage 716 storing an operating system 717, programs or applications 718 such as applications for controlling the EUV lithography tool 2, the mask handling system 3, the inspection tool 102, and/or the conditioning unit 104. The processor 712 can be a general-purpose microprocessor, a microcontroller, or the like. The storage 716 can be a random access memory (RAM), a flash memory, a read-only memory (ROM), a hard or optical disk, or any other suitable storage device, for storing information and instructions to be executed by processor 712. The processor 712 and storage 716 can be supplemented by, or incorporated in, special purpose logic circuitry.

The network interface 715 can include networking interface cards, such as Ethernet cards and modems. In some embodiments, the input/output interface 714 is configured to connect to a plurality of devices, such as an input device and/or an output device. Example input devices include a keyboard and a pointing device, e.g., a mouse or a trackball, by which a user can provide input to the computing system 710. Example output devices include display devices, such as LED (light emitting diode) or LCD (liquid crystal display) screens for displaying information to the user.

The applications 718 can include instructions which, when executed by the computing system 710 (or a processor 712 thereof), causes the computing system 710 (or the processor 712 thereof) to control the EUV lithography tool 2, the mask handling system 3, the inspection tool 102, and/or the conditioning unit 104, and perform other operations, methods, and/or processes that are explicitly or implicitly described in the present disclosure.

The data 719 can include data including parameters used in the control operations, data that is received, for example, through the input/output interface 714 or through the network interface 715 transmitted from the EUV lithography tool 2, the mask handling system 3, the inspection tool 102, and/or the conditioning unit 104, data for displaying on the display 711, data that is transmitted to or from the EUV lithography tool 2, the mask handling system 3, the inspection tool 102, and/or the conditioning unit 104 via the network 740, or data generated during operation of the computing system 710.

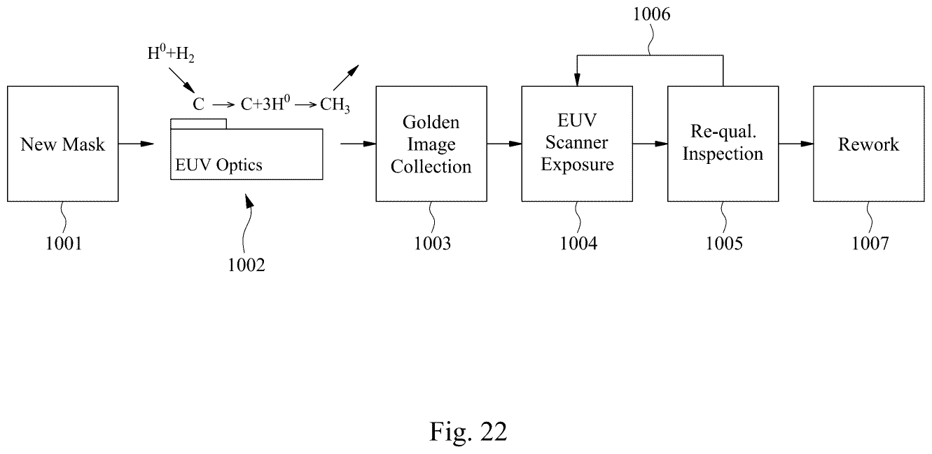

FIG. 22 illustrates a method manufacturing a semiconductor device according to some embodiments. The method includes obtaining a newly produced EUV mask 1001, conditioning the mask by exposing the reflective surface of the mask to hydrogen radicals 1002, and then capturing a golden image of the reflective surface of the mask 1003. The method also includes using the mask in a EUV lithography tool 1004 to conduct one or more photolithography processes. The method further includes, after the photolithography process, conducting a re-qualifying inspection of the EUV mask 1005 by capturing a second image of the reflective surface and comparing the second image with the golden image to determine whether one or more of a defect or contamination is present on the reflective surface. The method further includes returning the mask for use in the photolithography process 1006 upon determining that no defects or contamination are present on the reflective surface. The method further includes reworking the mask 1007 upon determining that a defect or contamination is present on the reflective surface. In some embodiments, reworking a mask 1007 to remove contamination includes conditioning the mask 1002 and collecting a golden image 1003 of the reflective surface of the mask.

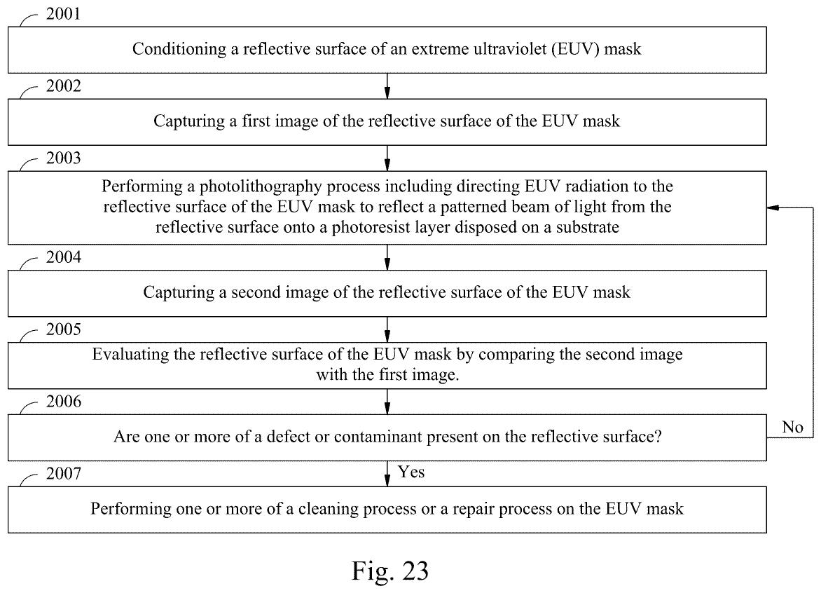

FIG. 23 illustrates another method of manufacturing a semiconductor device according to some embodiments. The method includes conditioning 2001 a reflective surface of an EUV mask. In some forms, the conditioning is conducted using one or more conditioning units and processing parameters disclosed herein. The conditioning can include removing organic material from the reflective surface. The conditioning can include reducing ruthenium oxide present on the reflective surface to ruthenium. After conditioning the reflective surface, the method includes capturing 2002 a first image of the reflective surface of the EUV mask. The first image can be a grayscale golden image captured by an inspection tool. After capturing the first image, the method includes performing 2003 a photolithography process including directing EUV radiation to the reflective surface of the EUV mask to reflect a patterned beam of light from the reflective surface onto a photoresist layer disposed on a substrate. The photolithography process can be repeated any desired number of iterations to process separate substrates and can be conducted using an EUV lithography tool as disclosed herein. After performing the photolithography process, the method includes capturing 2004 a second image of the reflective surface of the EUV mask. The second image can be a grayscale image captured by an inspection tool.

The method further includes evaluating 2005 the reflective surface of the EUV mask by comparing the second image with the first image. A computing system or inspection tool can conduct the comparison between the second image and the first image. The first and second grayscale images can each include a plurality of regions such that each region has a grayscale value. The reflective surface can be evaluated by comparing the grayscale value of each region of the second grayscale image with the grayscale value of a positionally corresponding region of the first grayscale image to determine whether the compared grayscale values are different. The evaluation of reflective surface can further include mapping a location on the reflective surface where the compared grayscale values are different.

In an embodiment, the method further includes determining 2006 whether one or more of a defect or a contaminant is present on the reflective surface upon evaluating the reflective surface 2005. In an embodiment, upon determining that the reflective surface is free of a defect or contamination, the method includes returning the EUV mask to the photolithography process 2003. In an embodiment, upon determining that the reflective surface has at least one of a defect or contamination, the method includes performing one or more of a cleaning process or a repair process on the EUV mask. In some embodiments, a cleaning process comprises conditioning 2001 the reflective surface of the EUV mask. In some embodiments, the cleaning process comprises cleaning the reflective surface with solvent. In some embodiments, a repair process includes processing the mask using focused ion-beam etching or focused-electron-beam-induced etching.

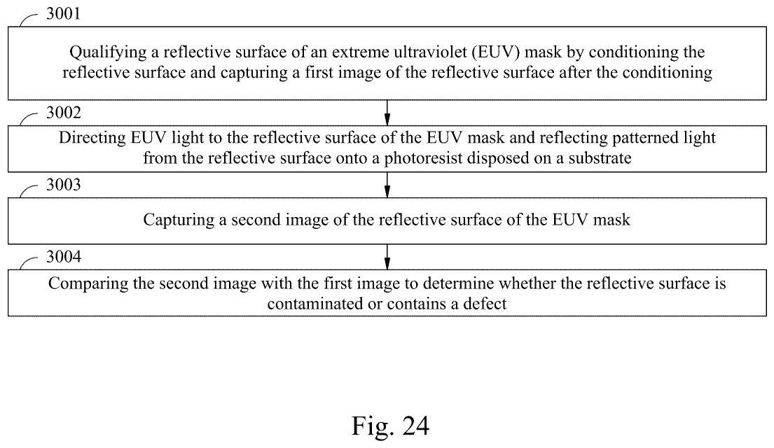

FIG. 24 illustrates yet another method of manufacturing a semiconductor device. The method includes qualifying 3001 a reflective surface of an EUV mask by conditioning the reflective surface and capturing a first image of the reflective surface after the conditioning. In some forms, the reflective surface of the EUV mask is qualified at a stage of new tape out of the EUV mask. In some aspects, the qualification of the reflective surface of the EUV mask is a requalification of the EUV mask that was previously used in an EUV photolithography process.

After qualifying the reflective surface, the method includes directing 3002 EUV light to the reflective surface of the EUV mask and reflecting patterned light from the reflective surface onto a photoresist disposed on a substrate. The method further includes capturing 3003 a second image of the reflective surface after reflecting the patterned light from the reflective surface. The method also includes comparing 3004 the second image with the first image to determine whether the reflective surface is contaminated or contains a defect.

The methods can be automated and controlled by a computing system as provided herein. The computing system can control a photolithography process in a photolithography tool, image captures in an inspection tool, conditioning in a conditioning unit, and transport of a mask through a mask handling system.

Embodiments of the present disclosure improve the efficiency mask inspection processes by reducing the bright-dark effect. Reducing the bright-dark effect can reduce the demand placed on inspection tools by reducing the number of golden images that may be captured of an individual mask. Reducing demand on inspection tools can increase semiconductor device production by reducing inspection bottleneck issues at the inspection tools. On the following basis, embodiments of the present disclosure can reduce demand on an inspection tool by 7.6 hours per day. For example, if 175 masks are used in production, and 8 new golden images are captured of the mask in a year due to the bright-dark effect, and it takes about 2.5 hours to generate a new golden image, at a golden image capture efficiency of 0.8:

$$( 175 \times 8 \times 2.5 hrs \times 0.8 ) / 365 = 7.6 hrs$$

According to an embodiment, a method of manufacturing a semiconductor device includes conditioning a reflective surface of an extreme ultraviolet (EUV) mask. The method includes, after conditioning the reflective surface, capturing a first image of the reflective surface of the EUV mask. The method includes, after capturing the first image, performing a photolithography process including directing EUV radiation to the reflective surface of the EUV mask to reflect a patterned beam of light from the reflective surface onto a photoresist layer disposed on a substrate. The method includes, after performing the photolithography process, capturing a second image of the reflective surface of the EUV mask. The method includes evaluating the reflective surface of the EUV mask by comparing the second image with the first image. In an embodiment, conditioning the reflective surface of the EUV mask includes removing organic material from the reflective surface. In an embodiment, conditioning the reflective surface includes reducing ruthenium oxide present on the reflective surface to ruthenium. In an embodiment, conditioning the reflective surface of the EUV mask includes treating the reflective surface with hydrogen radicals before placing the EUV mask in an EUV exposure device to perform the photolithography process. In an embodiment, conditioning the reflective surface of the EUV mask includes treating the reflective surface with ozone. In an embodiment, conditioning the reflective surface of the EUV mask includes performing an inductively coupled plasma reactive ion etching process on the reflective surface. In an embodiment, conditioning the reflective surface of the EUV mask includes thermally treating the reflective surface at a temperature sufficient to remove the organic material. In an embodiment, the method includes returning the EUV mask to the photolithography process upon determining that the reflective surface is free of a defect or contamination during the evaluation of the reflective surface, or performing one or more of a cleaning process or a repair process on the EUV mask upon determining that the reflective surface has at least one of a defect or contamination during the evaluation of the reflective surface. In an embodiment, the photolithography process includes performing a series of procedures on separate substrates, and during each procedure of the series of procedures directing the EUV radiation to the reflective surface of the EUV mask to reflect the patterned beam of light from the reflective surface onto the photoresist layer disposed on the substrate of the separate substrates.

According to another embodiment, a method of manufacturing a semiconductor device includes conditioning a reflective surface of an extreme ultraviolet (EUV) mask. The method includes capturing a first grayscale image of the conditioned reflective surface. The method includes, after capturing the first grayscale image, performing a photolithography process by reflecting EUV radiation from the reflective surface and onto a photoresist layer formed on a substrate. The method includes, after performing the photolithography process, capturing a second grayscale image of the reflective surface of the EUV mask. The method includes evaluating the reflective surface by comparing the second grayscale image with the first grayscale image. In an embodiment, the first and second grayscale images each include a plurality of regions, and each region of the plurality of regions has a grayscale value. In an embodiment, evaluating the reflective surface includes comparing the grayscale value of each region of the plurality of regions of the second grayscale image with the grayscale value of a positionally corresponding region of the plurality of regions of the first grayscale image to determine whether the compared grayscale values are different. In an embodiment, evaluating the reflective surface further includes mapping a location on the reflective surface where the compared grayscale values are different. In an embodiment, conditioning the reflective surface includes treating the reflective surface with hydrogen radicals when the EUV mask is in an environment outside a location where the photolithography process is performed. In an embodiment, conditioning the reflective surface includes removing organic material from the reflective surface. In an embodiment, conditioning the reflective surface includes reducing ruthenium oxide present on the reflective surface to ruthenium.

According to another embodiment, a method of manufacturing a semiconductor device includes qualifying a reflective surface of an extreme ultraviolet (EUV) mask by conditioning the reflective surface and capturing a first image of the reflective surface after the conditioning. The method includes, after qualifying the reflective surface, directing EUV light to the reflective surface of the EUV mask and reflecting patterned light from the reflective surface onto a photoresist disposed on a substrate. The method includes, capturing a second image of the reflective surface after reflecting the patterned light from the reflective surface. The method includes, comparing the second image with the first image to determine whether the reflective surface is contaminated or contains a defect. In an embodiment, qualifying the reflective surface of the EUV mask is performed at a time of new tape out of the EUV mask. In an embodiment, qualifying the reflective surface of the EUV mask is a requalification of the EUV mask that was previously used in an EUV photolithography process. In an embodiment, qualifying the reflective surface includes treating the reflective surface with hydrogen radicals in an environment outside an EUV exposure device. In an embodiment, qualifying the reflective includes at least one of: removal of organic material from the reflective surface, and reduction of ruthenium oxide on the reflective surface to ruthenium.

According to another embodiment, an extreme ultraviolet (EUV) photolithography system includes a conditioning unit configured to perform conditioning of a reflective surface of a EUV mask, wherein the conditioning includes at least one of removing organic material from the reflective surface, and reducing ruthenium oxide on the reflective surface to ruthenium. The system includes an inspection tool configured to capture images of the reflective surface. The system includes an EUV exposure device configured to perform a photolithography process including directing EUV radiation to the reflective surface to reflect a patterned beam of light from the reflective surface onto a photoresist layer disposed on a substrate. The system includes a computing system programmed to conduct operations including: controlling the conditioning unit to perform the conditioning of the reflective surface before the photolithography process, controlling the inspection tool to capture a first image of the reflective surface after the conditioning of the reflective surface, controlling the EUV exposure device to perform the photolithography process after the inspection tool captures the first image, controlling the inspection tool to capture a second image of the reflective surface after the photolithography process, and comparing the second image with the first image to determine the presence of at least one of a defect or contamination on the reflective surface. In an embodiment, the conditioning unit is disposed outside the EUV exposure device and is configured to treat the reflective surface of the EUV mask with hydrogen radicals. In an embodiment, the conditioning unit is configured to generate the hydrogen radicals. In an embodiment, the conditioning unit is configured to treat the reflective surface of the EUV mask with ozone. In an embodiment, the conditioning unit is configured to perform an inductively coupled plasma reactive ion etching process on the reflective surface. In an embodiment, the conditioning unit is configured to perform thermal processing of the reflective surface at a temperature sufficient to remove the organic material. In an embodiment, the EUV exposure device is configured to perform the photolithography process including performing a series of procedures on separate substrates, and during each procedure of the series of procedures the EUV radiation is directed to the reflective surface of the EUV mask to reflect the patterned beam of light from the reflective surface onto the photoresist layer disposed on the substrate of the separate substrates. In an embodiment, the computing system is programmed to control the inspection tool to capture the first image before the EUV exposure device performs the series of procedures and capture the second image after the EUV exposure device performs the series of procedures.

According to another embodiment, an extreme ultraviolet (EUV) photolithography system includes a conditioning unit configured to perform conditioning of a reflective surface of the EUV mask. The system includes an optical inspection tool configured to capture grayscale images of the reflective surface. The system includes an EUV apparatus configured perform a photolithography process including generating EUV radiation, and reflecting the EUV radiation from the reflective surface onto a photoresist layer disposed on a substrate. The system includes a computing system programmed to perform operations including: controlling the conditioning unit to perform the conditioning of the reflective surface, controlling the optical inspection tool to capture a first grayscale image of the reflective surface after the conditioning of the reflective surface, controlling the EUV apparatus to perform the photolithography process after the optical inspection tool captures the first grayscale image, controlling the optical inspection tool to capture a second grayscale image of the reflective surface after the photolithography process, and evaluate the reflective surface by comparing the second grayscale image with the first grayscale image. In an embodiment, the first and second grayscale images each include a plurality of regions, and each region of the plurality of regions has a grayscale value. In an embodiment, the computing system is programmed to compare the grayscale value of each region of the plurality of regions of the second grayscale image with the grayscale value of a positionally corresponding region of the plurality of regions of the first grayscale image. In an embodiment, the computing system is programmed to map a location on the reflective surface of where the compared grayscale values are different. In an embodiment, the conditioning unit is configured to treat the reflective surface with hydrogen radicals. In an embodiment, the conditioning unit is configured to remove organic material from the reflective surface using the hydrogen radicals. In an embodiment, the conditioning unit is further configured to reduce ruthenium oxide present on the reflective surface to ruthenium using the hydrogen radicals.

According to another embodiment, an extreme ultraviolet (EUV) photolithography system includes an EUV exposure device configured to perform a photolithography process including directing EUV radiation to a reflective surface of an EUV mask, reflecting patterned light from the reflective surface, and exposing a photoresist layer disposed on a substrate to the patterned light. The system includes an inspection tool configured to capture a first image of the reflective surface of the EUV mask before reflecting the patterned light from the reflective surface in the EUV exposure device, and capture a second image of the reflective surface after reflecting the patterned light from the reflective surface in the EUV exposure device. The system includes a conditioning unit configured to perform at least one of removing organic material from the reflective surface and reducing ruthenium oxide on the reflective surface to ruthenium, before the inspection tool captures the first image. The system includes a computing system configured to compare the second image with the first image to determine the presence of at least one of a defect or contamination on the reflective surface. In an embodiment, the conditioning unit is configured to treat the reflective surface with hydrogen radicals. In an embodiment, the conditioning unit includes a head configured to deliver diatomic hydrogen, a heating element configured to split the diatomic hydrogen into the hydrogen radicals, and a stage configured to support the EUV mask to permit the hydrogen radicals to contact the reflective surface. In an embodiment, the optical inspection tool includes the conditioning unit. In an embodiment, the conditioning unit is configured to treat the reflective surface with ozone.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device comprising:
conditioning a reflective surface of an extreme ultraviolet (EUV) mask;
after the conditioning the reflective surface, capturing a first image of the reflective surface of the EUV mask;
after the capturing the first image, performing a photolithography process including directing EUV radiation to the reflective surface of the EUV mask to reflect a patterned beam of light from the reflective surface onto a photoresist layer disposed on a substrate;
after the performing the photolithography process, capturing a second image of the reflective surface of the EUV mask; and
evaluating the reflective surface of the EUV mask by comparing the second image with the first image.

2. The method of claim 1, wherein the conditioning the reflective surface of the EUV mask comprises removing organic material from the reflective surface.

3. The method of claim 1, wherein the conditioning the reflective surface comprises reducing ruthenium oxide present on the reflective surface to ruthenium.

4. The method of claim 1, wherein the conditioning the reflective surface of the EUV mask comprises treating the reflective surface with hydrogen radicals before placing the EUV mask in an EUV exposure device to perform the photolithography process.

5. The method of claim 1, wherein the conditioning the reflective surface of the EUV mask comprises treating the reflective surface with ozone.

6. The method of claim 1, wherein the conditioning the reflective surface of the EUV mask comprises performing an inductively coupled plasma reactive ion etching process on the reflective surface.

7. The method of claim 2, wherein the conditioning the reflective surface of the EUV mask comprises thermally treating the reflective surface at a temperature sufficient to remove the organic material.

8. The method of claim 1, further comprising returning the EUV mask to the photolithography process upon determining that the reflective surface is free of a defect or contamination during the evaluating the reflective surface, or performing one or more of a cleaning process or a repair process on the EUV mask upon determining that the reflective surface has at least one of a defect or contamination during the evaluating the reflective surface.

9. A method of manufacturing a semiconductor device comprising:
qualifying a reflective surface of an extreme ultraviolet (EUV) mask by conditioning the reflective surface and capturing a first image of the reflective surface after the conditioning;
after qualifying the reflective surface, directing EUV light to the reflective surface of the EUV mask and reflecting patterned light from the reflective surface onto a photoresist disposed on a substrate;
capturing a second image of the reflective surface after the reflecting the patterned light from the reflective surface; and
comparing the second image with the first image to determine whether the reflective surface is contaminated or contains a defect.

10. The method of claim 9, wherein the qualifying the reflective surface of the EUV mask is performed at a time of new tape out of the EUV mask.

11. The method of claim 9, wherein the qualifying the reflective surface of the EUV mask is a requalification of the EUV mask that was previously used in an EUV photolithography process.

12. The method of claim 9, wherein the qualifying the reflective surface comprises treating the reflective surface with hydrogen radicals in an environment outside an EUV exposure device.

13. The method of claim 9, wherein the qualifying the reflective comprises at least one of:
removal of organic material from the reflective surface, and
reduction of ruthenium oxide on the reflective surface to ruthenium.

14. An extreme ultraviolet (EUV) photolithography system comprising:
a conditioning unit configured to perform conditioning of a reflective surface of a EUV mask, wherein the conditioning comprises at least one of removing organic material from the reflective surface, and reducing ruthenium oxide on the reflective surface to ruthenium;
an inspection tool configured to capture images of the reflective surface;
an EUV exposure device configured to perform a photolithography process including directing EUV radiation to the reflective surface to reflect a patterned beam of light from the reflective surface onto a photoresist layer disposed on a substrate; and
a computing system programmed to conduct operations comprising:
controlling the conditioning unit to perform the conditioning of the reflective surface before the photolithography process,
controlling the inspection tool to capture a first image of the reflective surface after the conditioning of the reflective surface,
controlling the EUV exposure device to perform the photolithography process after the inspection tool captures the first image,
controlling the inspection tool to capture a second image of the reflective surface after the photolithography process, and
comparing the second image with the first image to determine the presence of at least one of a defect or contamination on the reflective surface.

15. The system of claim 14, wherein the conditioning unit is disposed outside the EUV exposure device and is configured to treat the reflective surface of the EUV mask with hydrogen radicals.

16. The system of claim 15, wherein the conditioning unit is configured to generate the hydrogen radicals.

17. The system of claim 14, wherein the conditioning unit is configured to treat the reflective surface of the EUV mask with ozone.

18. The system of claim 14, wherein the conditioning unit is configured to perform an inductively coupled plasma reactive ion etching process on the reflective surface.

19. The system of claim 14, wherein the conditioning unit is configured to perform thermal processing of the reflective surface at a temperature sufficient to remove the organic material.

20. The system of claim 14, wherein the EUV exposure device is configured to perform the photolithography process comprising performing a series of procedures on separate substrates, and during each procedure of the series of procedures the EUV radiation is directed to the reflective surface of the EUV mask to reflect the patterned beam of light from the reflective surface onto the photoresist layer disposed on the substrate of the separate substrates.
